(19) United States
(12) Patent Application Publication
(10) Pub. No.: US 2008/0265283 A1
(43) Pub. Date: Oct. 30, 2008

(54) Hetero-junction bipolar transistor

(75) Inventor: Masanobu Nogome, Hyogo (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD., Osaka (JP)

(21) Appl. No.: 12/213,808

(22) Filed: Jun. 25, 2008

Related U.S. Application Data
(62) Division of application No. 11/498,737, filed on Aug. 4, 2006.

(30) Foreign Application Priority Data
Oct. 6, 2005 (JP) 2005-293774

(51) Int. Cl. H01L 29/739

(52) U.S. Cl. 257/197; 257/E29.189

(57) ABSTRACT

A hetero-junction bipolar transistor includes a sub-collector layer formed on a substrate and having conductivity, a first collector layer formed on the sub-collector layer and a second collector layer formed on the first collector layer and having the same conductive type as a conductive type of the sub-collector layer. In the first collector layer, a delta-doped layer is provided.

### CROSS-REFERENCE TO RELATED APPLICATION

The disclosure of Japanese Patent Applications No. 2005-293774 filed on Oct. 6, 2005 including specification, drawings and claims are incorporated herein by reference in its entirety.

### BACKGROUND OF THE INVENTION

The present invention relates to hetero-junction bipolar transistors.

Compound semiconductor devices such as a field-effect transistor (which will be hereafter referred to as a “FET”) or a hetero-junction bipolar transistor (HBT) are used for, for example, transmitting high output power amplifiers which are of a cellular phone component, and the like. In recent years, high output power characteristics, high gain characteristics and low distortion characteristics have been required for HBTs. To achieve those characteristics, the development of a high breakdown voltage and low on-state resistant HBT has been demanded.

Hereafter, a structure of a known HBT will be described with reference to FIG. 8 and Table 4. FIG. 8 is a cross-sectional view illustrating a structure of a first known HBT. Table 4 shows materials, conductivity types, film thicknesses and carrier concentrations for a substrate and each semiconductor layer in the first known HBT.

As shown in FIG. 8, a sub-collector layer 501, a second collector layer 503, a base layer 504, a first emitter layer 505, a second emitter layer 506 and an emitter contact layer 507 are formed in this order on a substrate 500 by crystal growth using MOCVD (metal organic chemical vapor deposition) or MBE (molecular beam epitaxy).

Then, process methods such as lithography, etching and deposition are performed to form, as shown in FIG. 8, a collector electrode 509 on the sub-collector layer 501, a base electrode 510 on the base layer 504 and an emitter electrode 511 on the emitter contact layer 507.

Table 4 shows materials, conductive types, film thicknesses and carrier concentrations for the substrate and each semiconductor layer of the first known HBT.

TABLE 4

| | | Conductive | | Carrier |
|---|---|---|---|---|
| Component names | Materials | type | Film thickness | concentration |
| Substrate500 | GaAs | | | |
| Sub-collector layer501 | GaAs | N | 600 nm | 5 × 10¹⁸[cm⁻³] |
| Second collector layer503 | GaAs | N | 600 nm | 1 × 10¹⁶[cm⁻³] |
| Base layer 504 | GaAs | P | | |
| First emitter layer505 | InGaP | N | | |
| Second emitter layer506 | GaAs | N | | |
| Emitter contact layer507 | InGaAs | N | | |

A structure of a second known HBT will be described with reference to FIG. 9. FIG. 9 is a cross-sectional view illustrating the structure of the second known HBT. In FIG. 9, each member also provided in the first known example is identified by the same reference numeral.

As shown in FIG. 9, the second known HBT differs from the first known HBT in that in the second known HBT, a first collector layer 402 of InGaP is provided so as to be interposed between a sub-collector layer 501 of n-type GaAs and a second collector layer 503 of n-type GaAs.

Advantages of providing the first collector layer 402 between the sub-collector layer 501 and the second collector layer 503 will be described with comparison between the first known HBT and the second known HBT.

First, electrical characteristics of the first known HBT and the second known HBT will be described with reference to FIGS. 10A and 10B.

FIG. 10A is a so-called “Gummel plot” showing the dependency of each of collector current Ic and base current Ib on base-emitter voltage Vbe when the first known HBT (see FIG. 8) is operated with the second collector layer 503 and the base layer 504 functioning as one component. In FIG. 10A, a line A indicates the relationship between the collector current Ic and the base-emitter voltage Vbe and a line B indicates the relationship between the base current Ib and the base-emitter voltage Vbe.

FIG. 10B is a graph showing the relationship (Ic-Vce characteristics) between collector current Ic and collector-emitter voltage Vce when each of the first known HBT and the second known HBT is operated with an emitter grounded. In FIG. 10B, a broken line indicates Ic-Vce characteristics for the first known HBT (see FIG. 8), and a solid line indicates Ic-Vce characteristics for the second known HBT (see FIG. 9). In this case, FIG. 10B shows the Ic-Vce characteristics where a desired Ib value (specifically, 0, Ibm/10, Ibm/2 and Ibm) is given. The Ibm value is a maximum value for Ib in FIG. 10A.

As shown in FIG. 10B, the graph shows that in the case where the Ib value is any one of 0, Ibm/10, Ibm/2 and Ibm, the Ic value is abruptly increased when a Vce value is increased to reach a certain value, so that the HBT is destroyed. Such abrupt increase in the Ic value with a certain Vce value is called “avalanche breakdown”.

“Avalanche breakdown” is the phenomenon in which when an increased reverse bias is applied between a collector and a base and then an electric field has become extremely high, electrons traveling in a collector layer at high speed are collided with surrounding atoms, so that electrons and holes are generated one after another. This phenomenon is also called “collision ionization”. In general, assuming that αn is a collision ionization coefficient for electrons, αp is a collision ionization coefficient for holes, Jn is a current density of electrons and Jp is a current density of holes, a current value with which avalanche breakdown is caused can be expressed by Expression 1.

αnJn+αpJp [Expression 1]

As shown in FIG. 10B, in either one of the first known HBT and the second known HBT, where the expression which indicates that the collector current Ic value is maximum, i.e., Ib=Ibm holds, the Vce value at a time when avalanche breakdown occurs becomes minimum. This shows that avalanche breakdown occurs depending on the amount of electrons or holes. That is, the larger the amount of electrons or holes is, the higher the possibility of occurrence of avalanche breakdown becomes.

As shown in FIG. 10B, in either one of the first known HBT and the second known HBT, where the expression which indicates that no carrier exists holds, i.e., Ib=0 holds, avalanche breakdown occurs at a time when an electric field intensity reaches a critical electric field intensity (e.g., 4×10⁵ V/cm). This shows that avalanche breakdown occurs depending on the electric field intensity. That is, the higher the electric field intensity is, the higher the possibility of occurrence of avalanche breakdown becomes.

As has been described, avalanche breakdown occurs depending on the amount of electrons, the amount of holes or the electric field intensity.

Next, how the first known HBT (see FIG. 8) is internally operated during a low current operation and during a high current operation will be described with reference to FIGS. 11A and 11B and FIGS. 12A and 12B (see, for example, William Liu, Fundamentals of III-V Devices, 1^{st} edition, USA, Wiley-Interscience, Mar. 24, 1999, pp. 186-193).

FIGS. 11A and 11B are graphs showing how the HBT is internally operated when the collector current Ic has a low current value, i.e., Ib=Ibm/10 (see FIG. 10B). FIGS. 12A and 12B are graphs showing how the HBT is internally operated when the collector current Ic has a high current value, i.e., Ib=Ibm (see FIG. 10B).

FIG. 11A and FIG. 12A are graphs showing donor concentration (which will be herein referred to as “design concentration”) and electron concentration. FIG. 11B and FIG. 12B are graphs showing electric field intensity (absolute value). Specifically, in each of FIG. 11A and FIG. 12A, the abscissa indicates a distance from a surface of the first emitter layer 505 on which the base layer 504 is formed to each semiconductor layer and the ordinate indicates the design concentration or the electron concentration. In each of FIG. 11B and FIG. 12B, the abscissa indicates a distance from the surface of the first emitter layer 505 on which the base layer 504 is formed to each semiconductor layer and the ordinate indicates the electric field intensity.

As shown in FIG. 11A, during a low current operation, the design concentration in the second collector layer 503 is higher than the electron concentration and the second collector layer 503 is positively charged therein. In this case, although not shown in the drawings, a surface of the base layer 504 on which the second collector layer 503 is formed includes a layer (specifically, a thin layer made of an ionized acceptor) which is negatively charged and negative charges in the layer and positive charges in the second collector layer 503 are in an equilibrium state.

As shown in FIG. 11B, during a low current operation, a high electric field corresponding to the critical electric field intensity (e.g., 4×10⁵V/cm) occurs at an interface between the base layer 504 and the second collector layer 503 and avalanche breakdown occurs.

This shows that when the collector current Ic is low, the HBT is destroyed due to the critical electric field intensity generated at the interface between the second collector layer 503 and the base layer 504.

As shown in FIG. 12A, during a high current operation, the design concentration in the second collector layer 503 is lower than the electric concentration and the second collector layer 503 is negatively charged therein. Although not shown in the drawings, a surface of the sub-collector 501 on which the second collector layer 503 is formed includes a layer which is positively charged and positive charges in the layer and the negative charges in the second collector layer 503 are in an equilibrium state.

As shown in FIG. 12B, during a high current operation, a maximum electric field is generated at the interface between the sub-collector layer 501 and the second collector layer 503 and avalanche breakdown occurs. In this manner, when a current is increased and electrons at a concentration exceeding the design concentration is injected to the second collector layer 503 (Kirk effect), a region in the second collector layer 503 to which the maximum electric field is applied is shifted from part of the second collector layer 503 located closer to the base layer to part of the second collector layer 503 located closer to the sub-collector layer. Accordingly, the maximum electric field is applied to an interface between the collector layer and the sub-collector layer, so that avalanche breakdown occurs at the interface between the collector layer and the sub-collector layer. In this case, the electron concentration in the sub-collector layer 501 is high and becomes in a state where avalanche breakdown easily occurs, and thus a maximum electric field intensity is lower than the critical electric field intensity (see FIG. 12B).

As has been described, when the collector current Ic is high, the HBT is destroyed due to the maximum electric field at the interface between the sub-collector layer 501 and the second collector layer 503.

Therefore, as a method for improving a breakdown voltage during a high current operation, for example, a method in which a first collector layer 402 of InGaP is provided so as to be interposed between the sub-collector layer 501 and the second collector layer 503, as in the second known HBT of FIG. 9, has been proposed (see, for example, Japanese Patent Laid-Open Publication No. 2005-39169).

In general, InGaP used as a material for constituting the first collector layer 402 has smaller collision ionization coefficients (αn and αp), compared to GaAs used as a material for constituting the sub-collector layer 501. Therefore, in the second known HBT, the first collector layer 402 of a material with a small collision ionization coefficient is interposed between the second collector layer 503 and the sub-collector layer 501 in which electric fields concentrate during a high current operation. Thus, as shown in FIG. 10B, in the second known HBT (see the solid line), avalanche breakdown occurs with a larger collector-emitter Vce value, compared to the first known HBT (see the broken line).

As described above, in the second known HBT, the first collector layer 402 is provided so as to be interposed between the sub-collector layer 501 and the second collector layer 503. Thus, a HBT in which avalanche breakdown hardly occurs and which has a high breakdown voltage can be realized.

However, in the second known HBT, the following problems arise. The problems of the second known HBT will be described with reference to FIG. 13. FIG. 13 is an illustration showing a band structure of the second known HBT.

In FIG. 13, a curve Ec indicates a conduction band and a curve Ev indicates a valence band. In FIG. 13, the ordinate indicates an energy value E (eV) for each of the conduction band and the valence band in each semiconductor layer and the abscissa denotes a distance Depth (nm) in the depth direction from a surface of the emitter contact layer 507 on which the emitter electrode 511 is formed to each semiconductor layer.

As shown in FIG. 13, since there is a difference between a band gap of InGaP used as the material for constituting the first collector layer 402 and a band gap of GaAs used as a material for constituting the second collector layer 503, discontinuity of the conduction band, the value ΔEc of which is about 0.2 eV, occurs at an interface between the second collector layer 503 and the first collector layer 402 (see the curve Ec). This causes a problem in which electrons traveling from the inside of the second collector layer 503 into the first collector layer 402 are affected by the discontinuity value (ΔEc) of 0.2 eV and an on-state resistance is increased.

As shown in FIG. 10B, in the second known HBT (see the solid line), compared to the first known HBT (see the broken line), the extent of a rise of the collector current Ic with respect to the collector-emitter voltage Vce is small in each of the cases where the Ib value is 0, where the Ib value is Ibm/10, where the Ib value is Ibm/2 and where the Ib value is Ibm.

Herein, the extent of a rise of the collector current Ic with respect to the collector-emitter voltage Vce corresponds to a reciprocal of an on-state resistance and the on-state resistance means to be the ratio of the collector-emitter voltage Vce to the collector current Ic. That is, in the second known HBT, compared to the first known HBT, the extent of the rise of the collector current Ic with respect to the collector-emitter voltage Vce is worse. This shows that the on-state resistance is high. Thus, with respect to the second known HBT, a HBT having a low on-state resistance can not be realized.

Furthermore, when the on-state resistance is high, reduction in the cutoff frequency ft which is an index of high frequency characteristics is caused. In general, assuming that τe is an emitter charging time, τb is a base transit time, τc is a collector depletion layer transit time and τcc is a collector charging time, the cutoff frequency ft can be expressed by Expression 2.

ft=½π(τe+τb+τc+τcc) [Expression 2]

With an increased on-state resistance, the collector depletion layer transit time τc is increased. As can be understood from Expression 2, increase in the collector depletion layer transit time τc causes reduction in the cutoff frequency ft.

As described above, there is another problem in which an increased on-state resistance causes reduction in the cutoff frequency ft and a HBT having excellent high frequency characteristics can not be realized.

### SUMMARY OF THE INVENTION

In view of the above-described technical problems, the present invention has been devised. It is therefore an object of the present invention is to provide a hetero-junction bipolar transistor (HBT) having a low on-state resistance and a high breakdown voltage.

To solve the above-described technical problems, a hetero-junction bipolar transistor according to a first aspect of the present invention is characterized by including: a sub-collector layer formed on a substrate and having conductivity; a first collector layer formed on the sub-collector layer; a second collector layer formed on the first collector layer and having the same conductive type as a conductive type of the sub-collector layer; and a delta-doped layer provided in the first collector layer.

In the hetero-junction bipolar transistor according to the first aspect of the present invention, a discontinuity value of a conduction band generated at an interface between the first collector layer and the second collector layer can be effectively reduced by adjusting band energy of a conduction band in part of the first collector layer in which the delta-doped layer is provided, so that discontinuity of the conduction band generated at the interface between the first collector layer and the second collector layer can be reduced.

Accordingly, increase in an on-state resistance due to influences of the discontinuity value of the conduction band generated at the interface between the second collector layer and the first collector layer on electrons traveling from the inside of the second collector layer into the first collector layer can be prevented. Therefore, a hetero-junction bipolar transistor having a low on-state resistance can be realized.

Furthermore, since increase in the on-state resistance can be prevented by effectively reducing the discontinuity of the conduction band generated at the interface between the first collector layer and the second collector layer, increase in a collector depletion layer transit time can be prevented. Accordingly, reduction in a cutoff frequency which is an index of high frequency characteristics can be prevented. Therefore, a hetero-junction bipolar transistor having excellent high frequency characteristics can be provided.

With the first collector layer provided between the sub-collector layer and the second collector layer, a hetero-junction bipolar transistor in which avalanche breakdown hardly occurs and which has a high breakdown voltage can be realized. As has been described, in the hetero-junction bipolar transistor according to the first aspect of the present invention, the delta-doped layer is provided in the first collector layer, so that a hetero-junction bipolar transistor having a high breakdown voltage can be realized without increasing the on-state resistance.

In the hetero-junction bipolar transistor according to the first aspect of the present invention, it is preferable that part of the first collector layer in which the delta-doped layer is provided is located in a higher position than a center of the first collector layer.

Thus, the part of the first collector layer in which the delta-doped layer is provided is located closer to the interface between the first collector layer and the second collector layer than the interface between the sub-collector layer and the first collector layer. Therefore, the discontinuity value of the conduction band generated at the interface between the first collector layer and the second collector layer can be effectively reduced by adjusting the band energy of the conduction band in the part of the first collector layer in which the delta-doped layer is provided.

Accordingly, increase in the on-state resistance due to influences of the discontinuity value of the conduction band generated at the interface between the second collector layer and the first collector layer on electrons traveling from the inside of the second collector layer into the first collector layer can be prevented. Therefore, a hetero-junction bipolar transistor having a low on-state resistance can be realized.

In the hetero-junction bipolar transistor according to the first aspect of the present invention, it is preferable that the first collector layer contains InGaP, the second collector layer contains GaAs, and the delta-doped layer contains an impurity having the same conductive type as the conductive type of the sub-collector layer.

Thus, the band energy of the conduction band in the part of the first collector layer in which the delta-doped layer is provided can be pulled down in the negative direction, for example, by adjusting a sheet concentration of the delta-doped layer to be a desired sheet concentration (e.g., 2×10¹² cm⁻²), so that the discontinuity value of the conduction band generated at the interface between the first collector layer and the second collector layer can be pulled down. Accordingly, the discontinuity value of the conduction band generated at the interface between the first collector layer and the second collector layer can be effectively reduced, and therefore the discontinuity of the conduction band generated at the interface between the first collector layer and the second collector layer can be reduced.

A hetero-junction bipolar transistor according to a second aspect of the present invention is characterized by including: a sub-collector layer formed on a substrate and having conductivity; a first collector layer formed on the sub-collector layer; a second collector layer formed on the first collector layer and having the same conductive type as a conductive type of the sub-collector layer; and a semiconductor layer provided between the first collector layer and the second collector layer so as to have a composition ratio varying in the direction from part of the semiconductor layer located closer to the first collector layer to part of the semiconductor layer located closer to the second collector layer.

In the hetero-junction bipolar transistor according to the second aspect of the present invention, the composition ratio of the semiconductor layer provided between the first collector layer and the second collector layer is adjusted so as to vary in the direction from part of the semiconductor layer located closer to the first collector layer to part of the semiconductor layer located closer to the second collector layer. Thus, a band gap of the semiconductor layer can be adjusted so as to vary in the direction from the part of the semiconductor layer located closer to the first collector layer to the part of the semiconductor layer located closer to the second collector layer, so that discontinuity of a conduction band generated at an interface of the semiconductor layer with the first collector layer can be reduced or eliminated and discontinuity of a conduction band generated at an interface of the semiconductor layer with the second collector layer can be reduced or eliminated.

For example, a composition ratio at the interface of the semiconductor layer with the first collector layer is adjusted so that discontinuity of the conduction band at the interface of the semiconductor layer with the first collector layer does not occur and a composition ratio at the interface of the semiconductor layer with the second collector layer is adjusted so that discontinuity of the conduction band at the interface of the semiconductor layer with the second collector layer does not occur. Thus, discontinuity does not occur at the interface of the semiconductor layer with the first collector layer and at the interface of the semiconductor layer with the second collector layer, so that the discontinuity of the conduction band generated between the first collector layer and the second collector layer can be eliminated.

Accordingly, increase in an on-state resistance due to influences of the discontinuity value of the conduction band generated at the interface between the second collector layer and the first collector layer on electrons traveling from the inside of the second collector layer into the first collector layer through the semiconductor layer can be prevented. Therefore, a hetero-junction bipolar transistor having a low on-state resistance can be realized.

Furthermore, since increase in the on-state resistance can be prevented by reducing or eliminating the discontinuity of the conduction band generated between the first collector layer and the second collector layer, increase in a collector depletion layer transit time can be prevented. Accordingly, reduction in a cutoff frequency which is an index of high frequency characteristics can be prevented. Therefore, a hetero-junction bipolar transistor having excellent high frequency characteristics can be provided.

With the first collector layer provided between the sub-collector layer and the second collector layer, a hetero-junction bipolar transistor in which avalanche breakdown hardly occurs and which has a high breakdown voltage can be realized. As has been described, in the hetero-junction bipolar transistor according to the second aspect of the present invention, the semiconductor layer is provided between the first collector layer and the second collector layer, so that a hetero-junction bipolar transistor having a high breakdown voltage can be realized without increasing the on-state resistance.

In the hetero-junction bipolar transistor according to the second aspect of the present invention, it is preferable that the first collector layer contains InGaP, the second collector layer contains GaAs, the semiconductor layer contains a compound expressed by a general formula of AlₓGa_{|1-x|}As where 0≦x≦1, and an x value in the general formula is reduced in the direction from an interface of the semiconductor layer with the first collector layer to an interface of the semiconductor layer with the second collector layer.

Thus, by adjusting the x value for the semiconductor layer of AlₓGa_{|1-x|}As so as to be reduced in the direction from the interface of the semiconductor layer with the first collector layer to the interface of the semiconductor layer with the second collector layer, the band gap of the semiconductor layer can be adjusted so as to be reduced in the direction from the interface of the semiconductor layer with the first collector layer to the interface of the semiconductor layer with the second collector layer. Accordingly, the discontinuity of the conduction band generated at the interface between the first collector layer of InGaP and the semiconductor layer can be reduced or eliminated and the discontinuity of the conduction band generated at the interface between the semiconductor layer and the second collector layer of GaAs can be reduced or eliminated.

In the hetero-junction bipolar transistor according to the second aspect of the present invention, it is preferable that the x value is 0.25 at the interface of the semiconductor layer with the first collector layer and the x value is 0 at the interface of the semiconductor layer with the second collector layer.

Thus, the discontinuity of the conduction band generated at the interface between the first collector layer of InGaP and the semiconductor layer of Al_{0.25}Ga_{0.75}As can be eliminated and the discontinuity of the conduction band generated at the interface between the semiconductor layer of GaAs and the second collector layer of GaAs can be eliminated.

A hetero-junction bipolar transistor according to a third aspect of the present invention is characterized by including: a sub-collector layer formed on a substrate and having conductivity; a first collector layer formed on the sub-collector layer; a second collector layer formed on the first collector layer and having the same conductive type as a conductive type of the sub-collector layer; and a spacer layer formed between the first collector layer and the second collector layer and having the same conductive type as the conductive type of the sub-collector layer.

In the hetero-junction bipolar transistor according to the third embodiment of the present invention, a concentration of the spacer layer provided between the first collector layer and the second collector layer is adjusted, so that discontinuity of a conduction band generated between the first collector layer and the second collector layer can be reduced.

Thus, increase in an on-state resistance due to influences of a discontinuity value of the conduction band generated at the interface between the second collector layer and the first collector layer on electrons traveling from the inside of the second collector layer into the first collector layer through the spacer layer. Therefore, a hetero-junction bipolar transistor having a low on-state resistance can be realized.

Furthermore, since increase in the on-state resistance can be prevented by reducing the discontinuity of the conduction band generated between the first collector layer and the second collector layer, increase in a collector depletion layer transit time can be prevented. Accordingly, reduction in a cutoff frequency which is an index of high frequency characteristics can be prevented. Therefore, a hetero-junction bipolar transistor having excellent high frequency characteristics can be provided.

With the first collector layer provided between the sub-collector layer and the second collector layer, a hetero-junction bipolar transistor in which avalanche breakdown hardly occurs and which has a high breakdown voltage can be realized. As has been described, in the hetero-junction bipolar transistor according to the third aspect of the present invention, the spacer layer is provided between the first collector layer and the second collector layer, so that a hetero-junction bipolar transistor having a high breakdown voltage can be realized without increasing the on-state resistance.

In the hetero-junction bipolar transistor according to the third aspect of the present invention, it is preferable that the first collector layer contains InGaP, the second collector layer contains GaAs, the spacer layer contains GaAs, and the spacer layer has a higher concentration than a concentration of the second collector layer.

With the spacer layer provided between the first collector layer and the second collector layer and having a higher concentration than the concentration of the second collector layer, band energy of a conduction band of the spacer layer can be adjusted so as to be smaller than band energy of a conduction band of the second collector layer, and the band energy of the conduction band of the spacer layer can be pulled down in the negative direction to reach the band energy of the conduction band of the second collector layer. Thus, the band energy of the conduction band at the interface of the first collector layer with the spacer layer can be pulled down in the negative direction, so that a discontinuity value of the conduction band generated at the interface between the spacer layer and the first collector layer can be effectively reduced.

Accordingly, increase in the on-state resistance due to influences of the discontinuity value of the conduction band generated at the interface between the second collector layer and the first collector layer on electrons traveling from the inside of the second collector layer into the first collector layer through the spacer layer can be prevented.

In the hetero-junction bipolar transistor according to the third aspect of the present invention, it is preferable that the spacer layer has a thickness of 10 nm or less, and the spacer layer has a concentration of 1×10¹⁸ cm⁻³ or more and 2×10¹⁸ cm⁻³ or less.

Thus, by adjusting the concentration of the spacer layer so as to be within a range from 1×10¹⁸ cm⁻³ or more and 2×10¹⁸ cm⁻³ or less, an electric field concentration in the spacer layer which will be a starting point of breakdown of the hetero-junction bipolar transistor can be suppressed. A breakdown resistance of the hetero-junction bipolar transistor depends on the concentration of an impurity contained in the spacer layer. Specifically, when the impurity concentration exceeds 2×10¹⁸ cm⁻³, the breakdown resistance of the hetero-junction bipolar transistor is drastically reduced and breakdown of the hetero-junction bipolar transistor is caused. Therefore, the concentration of the spacer layer is adjusted to be within the above-described range to suppress an electric field concentration in the spacer layer which will be a starting point of breakdown of the HBT.

Moreover, in this manner, as described above, the discontinuity value of the conduction band generated at the interface between the spacer layer and the first collector layer can be effectively reduced. Thus, increase in the on-state resistance due to influences of the discontinuity value of the conduction band generated between the second collector layer and the first collector layer on electrons traveling from the inside of the second collector layer into the first collector layer through the spacer layer can be prevented.

In each of the hetero-junction bipolar transistors according to the first through the third aspects of the present invention, it is preferable that the first collector layer has the same conductive type as a conductive type of the sub-collector layer or does not have a conductive type.

As has been described, in each of the hetero-junction bipolar transistors (HBTs) according to the first through third aspects of the present invention, the delta-doped layer is provided in the first collector layer or the semiconductor layer or the spacer layer is provided between the first collector layer and the second collector layer. Thus, a HBT having a high breakdown resistance without increasing an on-state resistance in a high output power operation can be realized, and a HBT having excellent high frequency characteristics can be provided.

### BRIEF DESCRIPTION OF THE DRAWINGS

FIG. 1 is a cross-sectional view illustrating a structure of a HBT according to a first embodiment of the present invention.

FIG. 2 is an illustration showing a band structure of the HBT according to the first embodiment of the present invention.

FIG. 3 is a graph showing Ic-Vce characteristics of the HBT according to the first embodiment of the present invention.

FIG. 4 is a cross-sectional view illustrating a structure of a HBT according to a second embodiment of the present invention.

FIG. 5 is an illustration showing a band structure of the HBT according to the second embodiment of the present invention.

FIG. 6 is a cross-sectional view illustrating a structure of a HBT according to a third embodiment of the present invention

FIG. 7 is an illustration showing a band structure of the HBT according to the third embodiment of the present invention.

FIG. 8 is a cross-sectional view illustrating a structure of a first known HBT.

FIG. 9 is a cross-sectional view illustrating a structure of a second known HBT.

FIG. 10A is a Gummel plot for the first known HBT and FIG. 10B is a graph showing Ic-Vce characteristics for each of the first known HBT and the second known HBT.

FIG. 11A is a graph showing design concentration and electron concentration in a second collector layer in the first known HBT in a low current operation and FIG. 11B is a graph showing electric field intensity in the second collector layer in the first known HBT in a low current operation.

FIG. 12A is a graph showing design concentration and electron concentration in a second collector layer in the first known HBT in a high current operation and FIG. 12B is a graph showing electric field intensity in the second collector layer in the first known HBT in a high current operation.

FIG. 13 is an illustration showing a band structure of the second known HBT.

### DESCRIPTION OF THE PREFERRED EMBODIMENTS

Hereafter, embodiments of the present invention will be described with reference to the accompanying drawings.

### First Embodiment

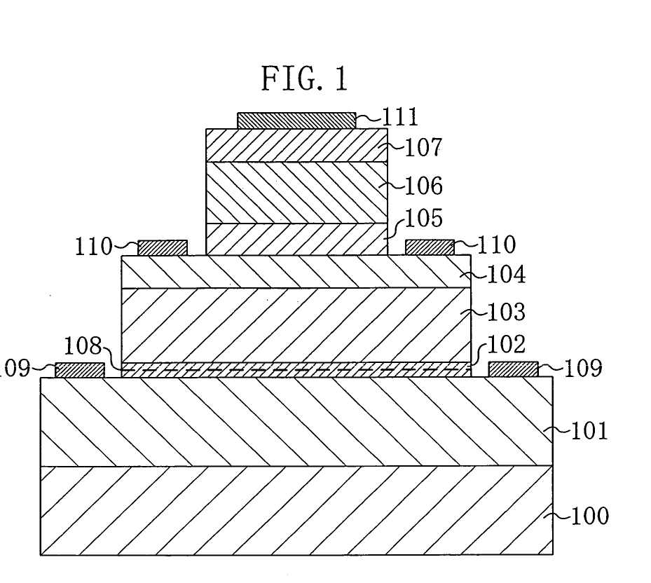

Hereafter, a structure of a HBT according to a first embodiment of the present invention will be described with reference to FIG. 1 and Table 1. FIG. 1 is a cross-sectional view illustrating the structure of the HBT according to the first embodiment of the present invention. Table 1 shows materials, conductivity types, film thicknesses, carrier concentrations and sheet concentrations for a substrate and each semiconductor layer in the HBT according to the first embodiment of the present invention.

An object of this embodiment is to realize a HBT having a low on-state resistance and a high breakdown voltage when the HBT is in a high output operation.

As shown in FIG. 1, a sub-collector layer 101, a first collector layer 102 including a delta-doped layer 108 therein, a second collector layer 103, a base layer 104, a first emitter layer 105, a second emitter layer 106 and an emitter contact layer 107 are formed in this order on a substrate 100 by MOCVD (metal organic chemical vapor deposition) or MBE (molecular beam epitaxy).

In this manner, as shown in FIG. 1, in the HBT of this embodiment, the delta-doped layer 108 containing an n-type impurity at a sheet concentration of 2×10¹² cm⁻² is provided in the first collector layer 102.

Then, process methods such as lithography, etching and deposition are performed to form, as shown in FIG. 1, a collector electrode 109 on the sub-collector layer 101, a base electrode 110 on the base layer 104 and an emitter electrode 111 on the emitter contact layer 107.

Table 1 shows materials, conductive types, film thicknesses and carrier concentrations for the substrate and each semiconductor layer in the HBT of this embodiment.

TABLE 1

| | | Conductive | | Carrier | Sheet |
|---|---|---|---|---|---|
| Component names | Materials | type | Film thickness | concentration | concentration |
| Substrate 100 | GaAs | | | | |
| Sub-collector layer101 | GaAs | N | 600 nm | 5 × 10¹⁸[cm⁻³] | |
| First collector layer102 | InGaP | | 100 nm | | |
| Delta-doped layer108 | | N | | | 2 × 10¹²[cm⁻²] |
| Second collector layer103 | GaAs | N | 500 nm | 1 × 10¹⁶[cm⁻³] | |
| Base layer104 | GaAs | P | | | |
| First emitter layer105 | InGaP | N | | | |
| Second emitter layer106 | GaAs | N | | | |
| Emitter contact layer107 | InGaAs | N | | | |

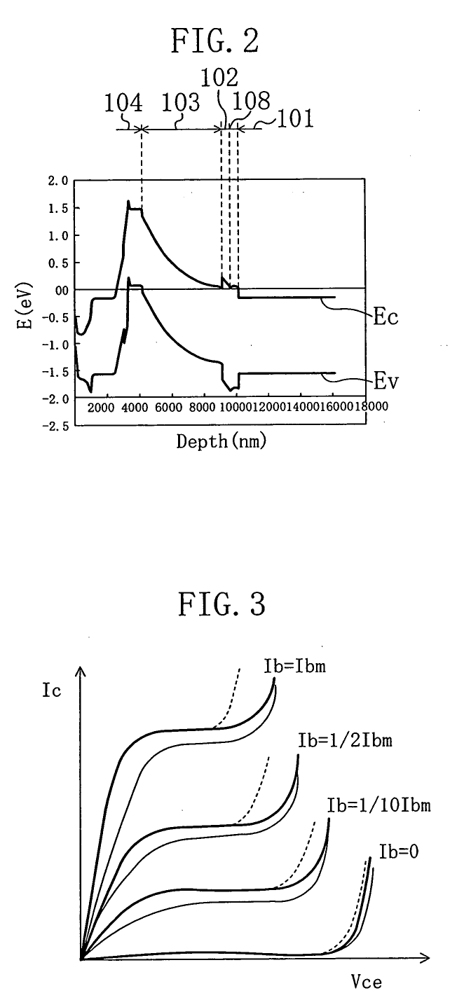

Next, the effects of the delta-doped layer 108 which is provided in the first collector layer 102 and is a feature of this embodiment will be described with reference to FIG. 2. FIG. 2 is an illustration showing a band structure of the HBT according to the first embodiment of the present invention.

In FIG. 2, a curve Ec indicates a conduction band and a curve Ev indicates a valence band. In FIG. 2, the ordinate indicates an energy value E (eV) for each of the conduction band and the valence band in each semiconductor layer and the abscissa denotes a distance Depth (nm) in the depth direction from a surface of the emitter contact layer 107 on which the emitter electrode 111 is formed to each semiconductor layer.

As shown in FIG. 2, by introduction of the delta-doped layer 108, band energy (see the curve Ec) of a conduction band in part of the first collector layer 102 in which the delta-doped layer 108 is provided is pulled down in the negative direction, so that discontinuity value ΔEc of a conduction band generated at an interface between the first collector layer 102 and the second collector layer 103 can be reduced.

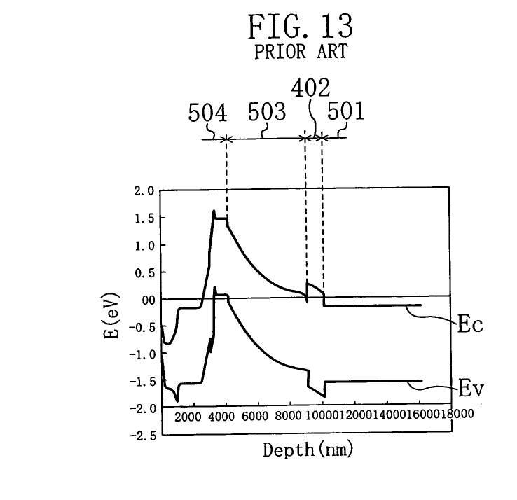

Thus, in the HBT of this embodiment, the discontinuity value ΔEc of the conduction band generated at the interface between the second collector layer 103 and the first collector layer 102 is effectively reduced. Accordingly, increase in an on-state resistance due to influences of the discontinuity value ΔEc of the conduction band generated in the interface between the second collector layer 103 and the first collector layer 102 on electrons traveling from the inside of the second collector layer 103 into the inside of the collector layer 102 can be prevented. Therefore, compared to the second known HBT (see FIG. 13), a HBT having a lower on-state resistance can be realized.

Next, electrical characteristics of the HBT of this embodiment will be described with reference to FIG. 3.

FIG. 3 is a graph showing Ic-Vce characteristics when each of the first known HBT, the second known HBT and the HBT of this embodiment is operated with an emitter grounded.

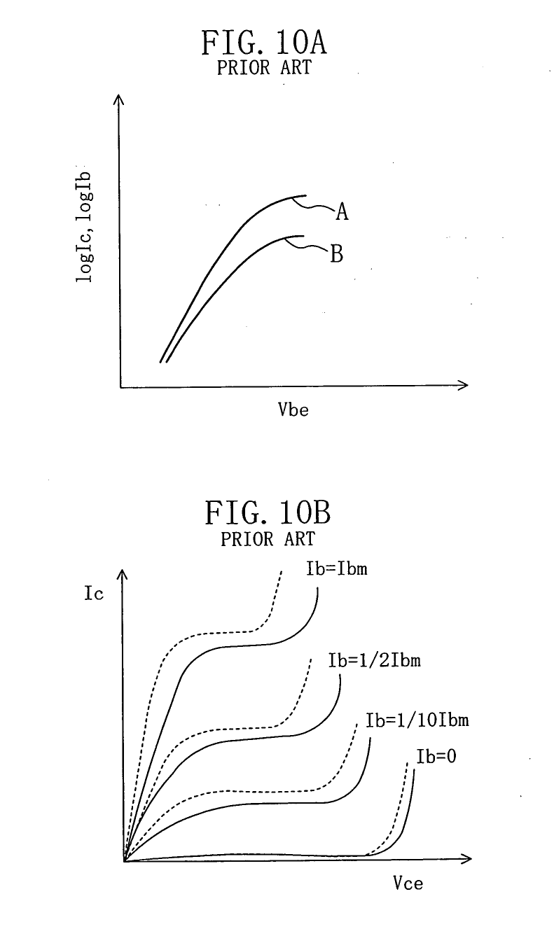

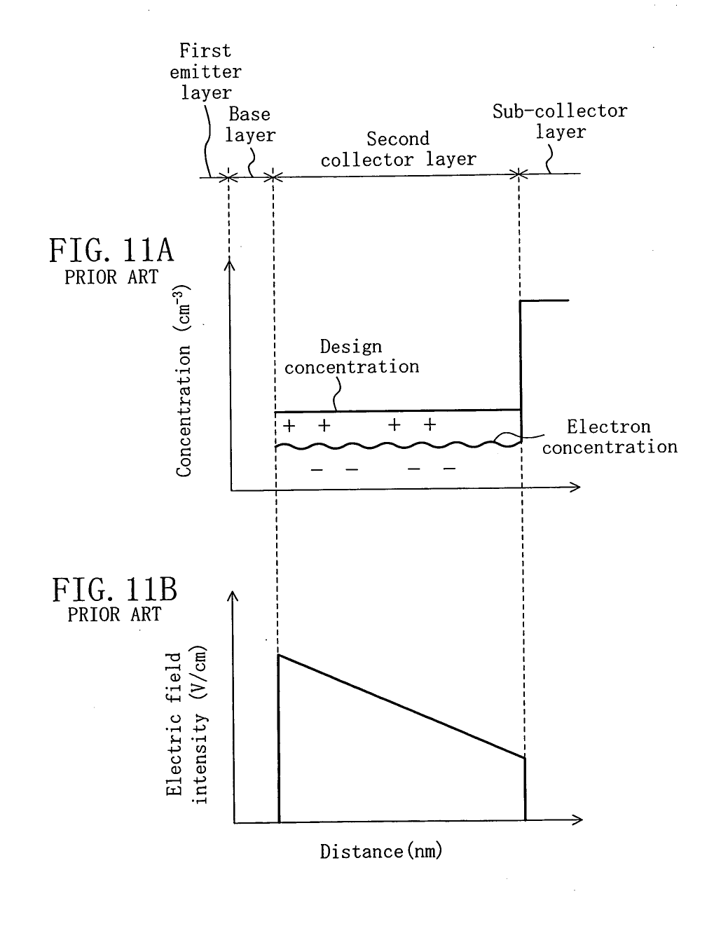

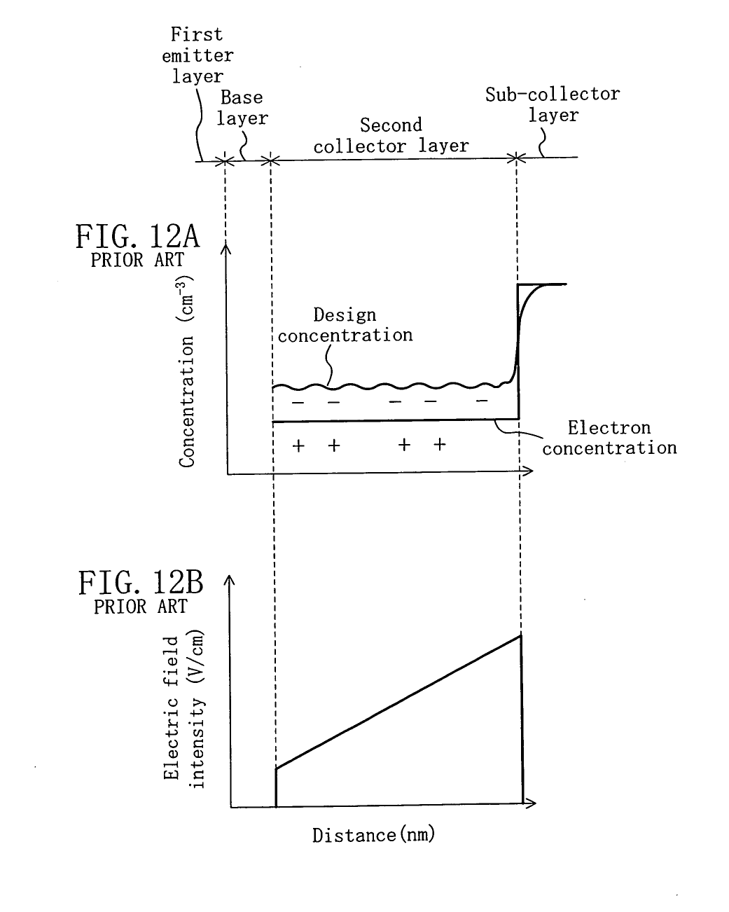

FIG. 3 shows Ic-Vce characteristics with a desired Ib value (specifically, 0, Ibm/10, Ibm/2 and Ibm). Herein, Ibm is a maximum value of Ib in FIG. 10A.

As shown in FIG. 3, according to this embodiment, compared to the first known HBT and the second known HBT, a HBT having a lower on-state resistance and a higher breakdown voltage can be realized.

Specifically, as shown in FIG. 3, in the HBT of this embodiment, the extent of a rise of Ic with respect to Vce is larger than the extent of a rise of Ic with respect to Vce in the second known HBT and the HBT of this embodiment has a lower on-state resistance.

Also, as shown in FIG. 3, the Ic value in the HBT of this embodiment is rapidly increased. That is, in this embodiment, a Vce value at which the HBT is destroyed is larger than a Vce value at which the first known HBT is destroyed and the HBT of this embodiment has a higher breakdown voltage.

As has been described, in the HBT of this embodiment, the discontinuity ΔEc of the conduction band generated at the interface between the first collector layer 102 and the second collector layer 103 can be effectively reduced by adjusting the band energy of the conduction band in the delta-doped layer 108 provided in the first collector layer 102. Therefore, the discontinuity of the conduction band generated at the interface between the first collector layer 102 and the second collector layer 103 can be reduced.

Thus, increase in the on-state resistance due to influences of the discontinuity value ΔEc of the conduction band generated at the interface between the second collector layer 103 and the first collector layer 102 on electrons traveling from the inside of the second collector layer 103 into the first collector layer 102 can be prevented. Therefore, a HBT having a low on-state resistance can be realized.

Furthermore, increase in the on-state resistance can be prevented by effectively reducing the discontinuity value ΔEc of the conduction band generated at the interface between the first collector layer 102 and the second collector layer 103, so that increase in the collector depletion layer transit time τC can be prevented. Thus, reduction in the cutoff frequency ft which is an index of high frequency characteristics can be prevented (see Expression 2) and, therefore, a HBT having excellent high frequency characteristics can be provided.

With the first collector layer 102 being interposed between the sub-collector layer 101 and the second collector layer 103, a HBT in which avalanche breakdown hardly occurs and which has a high breakdown voltage can be realized. As has been described, in the HBT of this embodiment, the delta-doped layer 108 is provided in the first collector layer 102. Thus, a HBT having a high breakdown voltage can be realized without increasing an on-state resistance.

### Second Embodiment

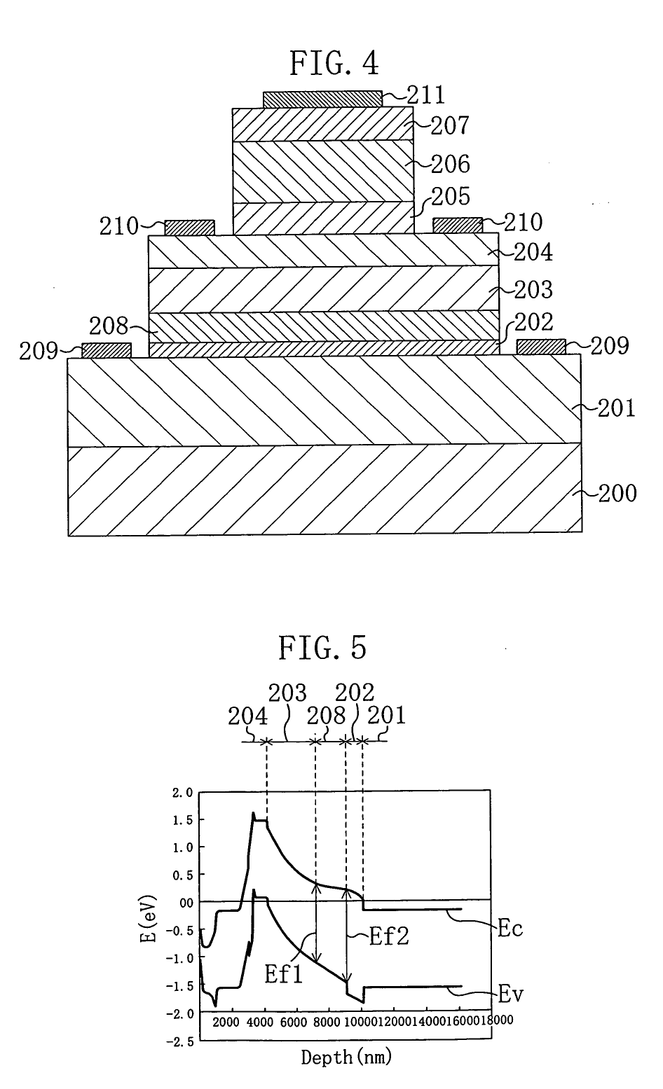

Hereafter, a structure of a HBT according to a second embodiment of the present invention will be described with reference to FIG. 4 and Table 2. FIG. 4 is a cross-sectional view illustrating the structure of the HBT according to the second embodiment of the present invention. Table 2 shows materials, conductive types, film thicknesses and carrier concentrations for a substrate and each semiconductor layer in the HBT according to the second embodiment of the present invention.

An object of this embodiment is the same as that of the first embodiment, i.e., to realize a HBT having a low on-state resistance and a high breakdown voltage when the HBT is in a high output operation.

As shown in FIG. 4, a sub-collector layer 201, a first collector layer 202, a composition-graded layer 208, a second collector layer 203, a base layer 204, a first emitter layer 205, a second emitter layer 206 and an emitter contact layer 207 are formed in this order on a substrate 200 by MOCVD (metal organic chemical vapor deposition) or MBE (molecular beam epitaxy).

In this manner, in the HBT of this embodiment, as shown in FIG. 4, the n-type AlₓGa_{|1-x|}As composition-graded collector layer 208 having a thickness of 200 nm and a concentration of 1×10¹⁶ cm⁻³ is formed between the first collector layer 202 and the second collector layer 203.

Then, process methods such as lithography, etching and deposition are performed to form, as shown in FIG. 4, a collector electrode 209 on the sub-collector layer 201, a base electrode 210 on the base layer 204 and an emitter electrode 211 on the emitter contact layer 207.

Table 2 shows materials, conductive types, film thicknesses and carrier concentrations for a substrate and each semiconductor layer in the HBT of this embodiment.

TABLE 2

| | | Conductive | | Carrier |
|---|---|---|---|---|
| Component names | Materials | type | Film thickness | concentration |
| Substrate200 | GaAs | | | |
| Sub-collector layer201 | GaAs | N | 600 nm | 5 × 10¹⁸[cm⁻³] |
| First collector layer202 | InGaP | | 100 nm | |
| Composition-graded | AlₓGa₍₁₋ₓ₎As | N | 200 nm | 1 × 10¹⁶[cm⁻³] |
| collector layer208 | | | | |
| Second collector layer203 | GaAs | N | 300 nm | 1 × 10¹⁶[cm⁻³] |
| Base layer204 | GaAs | P | | |
| First emitter layer205 | InGaP | N | | |
| Second emitter layer206 | GaAs | N | | |
| Emitter contact layer207 | InGaAs | N | | |

In this case, a composition ratio in the composition-graded collector layer 208 of AlₓGa_{|1-x|}As is adjusted so as to vary in the direction from the interface of the composition-graded collector layer 208 with the second collector layer 203 to the interface thereof with the first collector layer 202 so that a discontinuity value ΔEc (see FIG. 13) of a conduction band generated at an interface between the second collector layer 203 and the first collector layer 202 is reduced or eliminated.

Specifically, the composition ratio is adjusted so that an x value in the AlₓGa_{|1-x|}As which is a material used for constituting the composition-graded collector layer 208 is reduced in the direction from the interface of the composition-graded collector layer 208 with the first collector layer 202 to the interface thereof with the second collector layer 203, for example, the x value for the interface with the first collector layer 202 becomes 0.25 and the x value for the interface with the second collector layer 203 becomes 0.

As described above, the composition ratio of a material used for constituting the composition-graded collector layer 208 is adjusted, so that a band gap of the composition-graded collector layer 208 can be made to be gradually reduced in the direction from the interface of the composition-graded collector layer 208 with the first collector layer 202 to the interface thereof with the second collector layer 203 (see Ef in FIG. 5 which will be shown later).

Next, the effects of the composition-graded collector layer 208 which is provided between the first collector layer 202 and the second collector layer 203 and is a feature of this embodiment will be described with reference to FIG. 5. FIG. 5 is an illustration showing a band structure of the HBT according to the second embodiment of the present invention.

In FIG. 5, a curve Ec indicates a conduction band and a curve Ev indicates a valence band. In FIG. 5, the ordinate indicates an energy value E (eV) for each of the conduction band and the valence band in each semiconductor layer and the abscissa denotes a distance Depth (nm) in the depth direction from a surface of the emitter contact layer 207 on which the emitter electrode 211 is formed to each semiconductor layer.

As shown in FIG. 5, the composition ratio of a material used for constituting the composition-graded collector layer 208 is adjusted, so that a band gap of the composition-graded collector layer 208 can be made to be gradually increased in the direction from the interface of the composition-graded collector layer 208 with the second collector layer 203 to the interface thereof with the first collector layer 202.

For example, as shown in FIG. 5, the composition ratio of the material used for constituting the composition-graded collector layer 208 is adjusted so that the band gap at the interface of the composition-graded collector layer 208 with the second collector layer 203 becomes the same as the band gap of the second collector layer 203 (i.e., x=0). Also, as shown in FIG. 5, the composition ratio of the material used for constituting the composition-graded collector layer 208 is adjusted so that Ec at the interface of the composition-graded collector layer 208 with the first collector layer 202 becomes the same as Ec of the first collector layer 202 (e.g., x=0.25).

Thus, as shown in FIG. 5, since there is no difference between the band gap of the second collector layer 203 and the band gap of the composition-graded collector layer 208 (see Ef1), the discontinuity value ΔEc of the conduction band generated at the interface between the second collector layer 203 and the composition-graded collector layer 208 is eliminated. Also, since there is no difference between Ec of the composition-graded collector layer 208 and Ec of the first collector layer 202 (see Ef2), the discontinuity value ΔEc of the conduction band generated at the interface between the composition-graded collector layer 208 and the first collector layer 202 is eliminated.

Thus, increase in the on-state resistance due to influences of the discontinuity value ΔEc of the conduction band generated at the interface between the second collector layer 203 and the first collector layer 202 on electrons traveling from the inside of the second collector layer 203 into the first collector layer 202 through the composition-graded collector layer 208 can be prevented. Therefore, a HBT having a low on-state resistance can be realized.

Furthermore, by elimination of the discontinuity value ΔEc of the conduction band generated between the first collector layer 202 and the second collector layer 203, increase in the on-state resistance can be prevented and thus increase in the collector depletion layer transit time τc can be prevented. Therefore, reduction in the cutoff frequency ft which is an index of high frequency characteristics can be prevented (see Expression 2), so that a HBT having excellent high frequency characteristics can be provided.

With the first collector layer 202 provided between the sub-collector layer 201 and the second collector layer 203, a HBT in which avalanche breakdown hardly occurs and which has a high breakdown voltage can be realized. As has been described, in the HBT of this embodiment, the composition-graded collector layer 208 is provided between the first collector layer 202 and the second collector layer 203. Thus, a HBT having a high breakdown voltage can be realized without increasing an on-state resistance.

### Third Embodiment

Hereafter, a structure of a HBT according to a third embodiment of the present invention will be descried with reference to FIG. 6 and Table 3. FIG. 6 is a cross-sectional view illustrating the structure of the HBT according to the third embodiment of the present invention. Table 3 shows materials, conductive types, film thicknesses and carrier concentrations for a substrate and each semiconductor layer in the HBT according to the third embodiment of the present invention.

An object of this embodiment is the same as those of the first and second embodiments, i.e., to realize a HBT having a low on-state resistance and a high breakdown voltage when the HBT is in a high output operation.

As shown in FIG. 6, a sub-collector layer 301, a first collector layer 302, a spacer layer 308, a second collector layer 303, a base layer 304, a first emitter layer 305, a second emitter layer 306 and an emitter contact layer 307 are formed in this order on a substrate 300 by MOCVD (metal organic chemical vapor deposition) or MBE (molecular beam epitaxy).

Thus, in the HBT of this embodiment, as shown in FIG. 6, the heavily doped n-type GaAs spacer layer 308 having a thickness of 10 nm and a concentration of 2×10¹⁸ cm⁻³ is formed between the first collector layer 302 and the second collector layer 303.

Then, process methods such as lithography, etching and deposition are performed to form, as shown in FIG. 6, a collector electrode 309 on the sub-collector layer 301, a base electrode 310 on the base layer 304 and an emitter electrode 311 on the emitter contact layer 307.

Table 3 shows materials, conductive types, film thicknesses and carrier concentrations for the substrate and each semiconductor layer of the HBT of this embodiment.

TABLE 3

| | | Conductive | | Carrier |
|---|---|---|---|---|
| Component names | Materials | type | Film thickness | concentration |
| Substrate300 | GaAs | | | |
| Sub-collector layer301 | GaAs | N | 600 nm | 5 × 10¹⁸[cm⁻³] |
| First collector layer302 | InGaP | | 100 nm | |
| Spacer layer308 | GaAs | N | 10 nm | 2 × 10¹⁸[cm⁻³] |
| Second collector layer303 | GaAs | N | 500 nm | 1 × 10¹⁶[cm⁻³] |
| Base layer304 | GaAs | P | | |
| First emitter layer305 | InGaP | N | | |
| Second emitter layer306 | GaAs | N | | |
| Emitter contact layer307 | InGaAs | N | | |

As shown in Table 3, the spacer layer 308 has a higher concentration than the concentration of the second collector layer 303. Specifically, the concentration of the spacer layer 308 is adjusted within the range from 1×10¹⁸ cm⁻³ or more to 2×10¹⁸ cm⁻³ or less.

Thus, an electric field concentration in the spacer layer 308 which can be a starting point of breakdown of the HBT can be suppressed. A breakdown resistance of the HBT depends on the concentration of an impurity contained in the spacer layer 308. Specifically, when the impurity concentration exceeds 2×10¹⁸ cm⁻³, the breakdown resistance of the HBT is drastically reduced and breakdown of the HBT is caused. Therefore, by adjusting the concentration of the spacer layer 308 so as to be within the above-described range, an electric field concentration in the spacer layer 308 which will be a starting point of breakdown of the HBT can be suppressed.

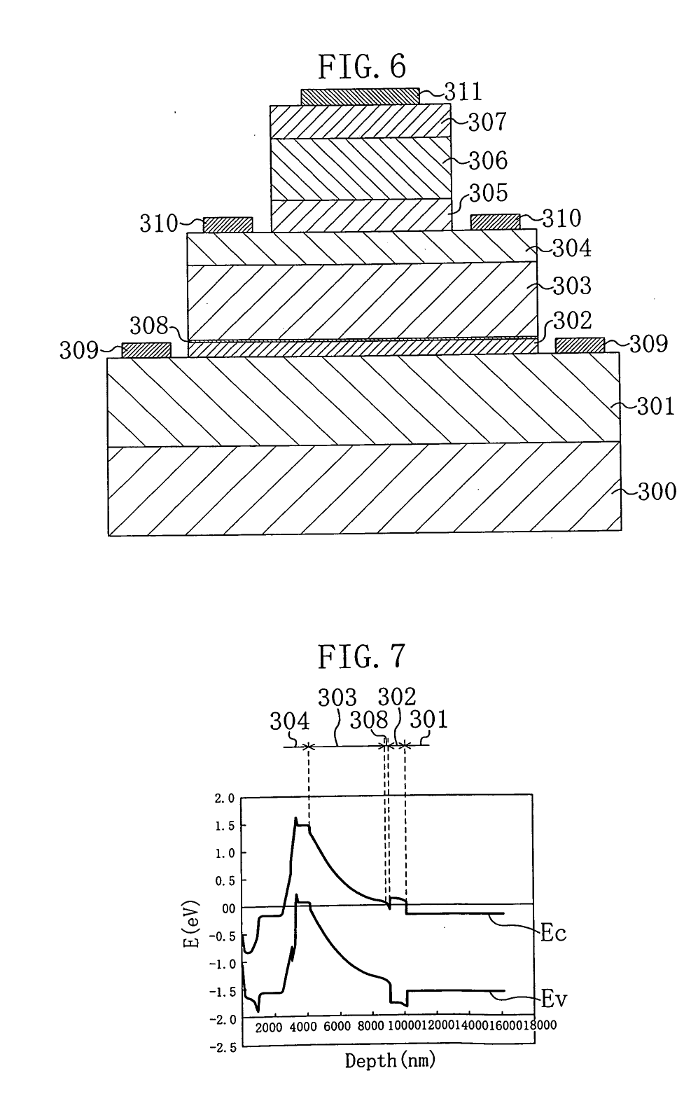

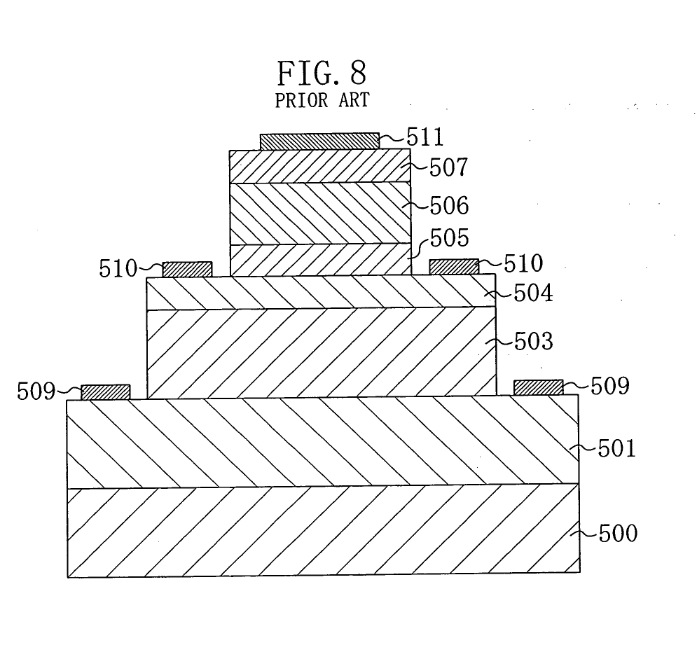

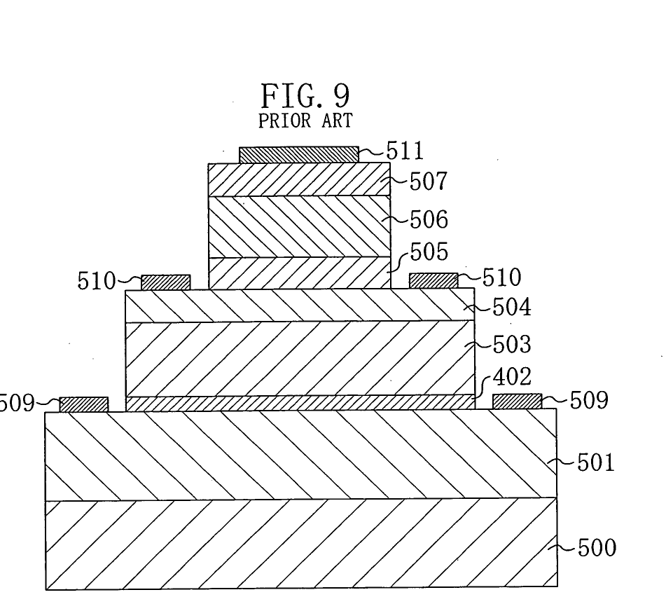

Next, the effects of the spacer layer 308 which is provided between the first collector layer 302 and the second collector layer 303 and is a feature of this embodiment will be described with reference to FIG. 7. FIG. 7 is an illustration showing a band structure of the HBT according to the third embodiment of the present invention.

In FIG. 7, a curve Ec indicates a conduction band and a curve Ev indicates a valence band. In FIG. 7, the ordinate indicates an energy value E (eV) for each of the conduction band and the valence band in each semiconductor layer and the abscissa denotes a distance Depth (nm) in the depth direction from a surface of the emitter contact layer 307 on which the emitter electrode 311 is formed to each semiconductor layer.

By introduction of the spacer layer 308 having a small thickness and containing an n-type impurity at a high concentration between the first collector layer 302 and the second collector layer 303, a structure in which a layer containing electrons at a high concentration locally exists between the first collector layer 302 and the second collector layer 303 is obtained. In such a structure, as shown in FIG. 7, band energy (see the curve Ec) of a conduction band of the spacer layer 308 is pulled down in the negative direction so as to reach a lower level than band energy of the second collector layer 303. Accordingly, band energy of a conduction band at the interface of the first collector layer 302 with the spacer layer 308 can be pulled down in the negative direction, so that the discontinuity value ΔEc of a conduction band generated in the interface between the spacer layer 308 and the first collector layer 302 can be effectively reduced.

Thus, increase in the on-state resistance due to influences of the discontinuity value between the second collector layer 303 and the first collector layer 302 (specifically, the discontinuity value of the conduction band generated at the interface between the spacer layer 308 and the first collector layer 302) on electrons traveling from the inside of the second collector layer 303 into the first collector layer 302 through the spacer layer 308 can be prevented. Therefore, a HBT having a low on-state resistance can be realized.

Furthermore, increase in the on-state resistance can be prevented by effectively reducing the discontinuity value ΔEc of the conduction band generated at the interface between the first collector layer 302 and the second collector layer 303, so that increase in the collector depletion layer transit time τc can be prevented. Accordingly, reduction in the cutoff frequency ft which is an index of high frequency characteristics can be prevented (see Expression 2) and, therefore, a HBT having excellent high frequency characteristics can be provided.

With the first collector layer 302 being interposed between the sub-collector layer 301 and the second collector layer 303, a HBT in which avalanche breakdown hardly occurs and which has a high breakdown voltage can be realized. As has been described, in the HBT of this embodiment, the spacer layer 308 is provided between the first collector layer 302 and the second collector layer 303. Thus, a HBT having a high breakdown voltage can be realized without increasing an on-state resistance.

Note that in the HBT of each of the first through third embodiments of the present invention, undoped InGaP is used for the first contact layer 102, 202 or 302. However, the present invention is not limited thereto but n-type InGaP can be used for the first contact layer.

As has been described, the present invention is useful for a hetero-junction bipolar transistor used for, for example, a transmitting high output power amplifier which is a cellular phone component or the like.

1-3. (canceled)

4. A hetero-junction bipolar transistor comprising:
a sub-collector layer formed on a substrate and having conductivity;
a first collector layer formed on the sub-collector layer;
a second collector layer formed on the first collector layer and having the same conductive type as a conductive type of the sub-collector layer; and
a semiconductor layer provided between the first collector layer and the second collector layer so as to have a composition ratio varying in the direction from part of the semiconductor layer located closer to the first collector layer to part of the semiconductor layer located closer to the second collector layer.

5. The hetero-junction bipolar transistor of claim 4, wherein the first collector layer contains InGaP,
wherein the second collector layer contains GaAs,
wherein the semiconductor layer contains a compound expressed by a general formula of AlₓGa_{|1-x|}As where 0≦x≦1, and
wherein an x value in the general formula is reduced in the direction from an interface of the semiconductor layer with the first collector layer to an interface of the semiconductor layer with the second collector layer.

6. The hetero-junction bipolar transistor of claim 5, wherein the x value is 0.25 at the interface of the semiconductor layer with the first collector layer and the x value is 0 at the interface of the semiconductor layer with the second collector layer.

7-10. (canceled)
